(19) United States
(12) Patent Application Publication
(10) Pub. No.: US 2024/0429896 A1
(43) Pub. Date: Dec. 26, 2024

(54) UTILIZING TRANSFORMER SECONDARY COIL FOR HARMONIC REJECTION FILTERING

(71) Applicant: Apple Inc., Cupertino, CA (US)

(72) Inventor: Ahmed G Radwan, Unterhaching (DE)

(21) Appl. No.: 18/213,669

(22) Filed: Jun. 23, 2023

(51) Int. Cl. H03H 11/04; H01F 27/28

(52) U.S. Cl. CPC H03H 11/04; H01F 27/28

(57) ABSTRACT

To reduce loss in a matching network without crowding the matching network transformer, a harmonic rejection inductor may be removed from the center of the transformer and an existing secondary coil (e.g., secondary inductor) of the transformer may be reused as the harmonic rejection inductor. The secondary coil may be reused as the harmonic rejection inductor by coupling a harmonic rejection capacitor directly to windings of the secondary coil, which may enable the portion of the secondary coil between the harmonic rejection capacitor tap point and ground to function as the harmonic rejection inductor.

### BACKGROUND

The present disclosure relates generally to wireless communication, and more specifically to harmonic rejection filtering in a transceiver.

In an electronic device, transmitter performance may be dependent upon a maximum achievable transmitter output power. Maximum achievable output power may be based at least in part on performance of a matching network. The matching network may be disposed in series with a power amplifier of the transmission chain, such that reducing loss in the matching network may increase maximum achievable output power. However, certain transmitter functions, such as transmitter harmonic rejection and functions that satisfy coexistence and crosstalk boundaries, may cause or increase loss in the matching network.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a transmitter includes a digital-to-analog converter (DAC); a first inductor coupled to the DAC; a second inductor inductively coupled to the first inductor, the second inductor including one or more windings; and a capacitor coupled at a first terminal of the capacitor to the one or more windings and at a second terminal of the capacitor to ground.

In another embodiment, a transformer includes a first inductor; and a second inductor configured to inductively couple to the first inductor and coupled to a capacitor, the capacitor coupled between windings of the second inductor and configured to perform harmonic rejection of designated harmonic, or both, of an input signal to the transformer.

In yet another embodiment, a system includes a digital-to-analog converter (DAC); a transformer coupled to an output of the DAC, the transformer including a first inductor including a first plurality of windings; and a second inductor including a second plurality of windings, the second inductor configured to inductively couple to the first inductor, a capacitor coupled at a tap point of the second plurality of windings; and an amplifier coupled to an output of the second inductor.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a schematic diagram of a matching network having a harmonic rejection inductor integrated into a secondary coil of a transformer of a matching network, according to embodiments of the present disclosure;

FIG. 6 is a plot illustrating output power of the transmitter of FIG. 3 when the transmitter is coupled to the matching network of FIG. 5 and when the transmitter is coupled to a matching network wherein the harmonic rejection inductor is not integrated into the secondary coil of the transformer, according to embodiments of the present disclosure; and

FIG. 7 is a plot illustrating harmonic rejection in the transmitter of FIG. 3 when the transmitter is coupled to the matching network of FIG. 5 and when the transmitter is coupled to a matching network wherein the harmonic rejection inductor is not integrated into the secondary coil of the transformer, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising.” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately.” “near.” “about.” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

Transmitter performance (e.g., efficiency, power consumption) may be dependent upon a maximum achievable transmitter output power. Maximum achievable output power may be based at least in part on performance of a matching network. The matching network may be disposed in series with a power amplifier (PA) of the transmission chain, such that reducing loss in the matching network may increase maximum achievable output power. However, certain transmitter functions, such as transmitter harmonic rejection and functions that satisfy coexistence and crosstalk boundaries, may increase loss in the matching network.

As more and more components are disposed in an area of a transformer, a quality (Q) factor of the transformer may decrease due to effects of the crowding. In some cases, to reduce or minimize the crowding effects, a harmonic rejection inductor may be disposed at the center of the transformer and a harmonic rejection capacitor may be coupled to the harmonic rejection inductor at the center of the transformer. However, this may result in drawbacks, such as a reduced Q factor of both the transformer and the harmonic rejection inductor due to the current crowding effect (e.g., a magnetic field compression and electric field loading between neighbor metals of the harmonic rejection coil and surrounding transformer metallization). Other drawbacks may include imposing a lower limit on the diameter of the innermost winding of the primary coil or the secondary coil of the transformer to fit the transformer and the harmonic rejection capacitor, which may result in a disadvantageous increase of area consumption.

To reduce matching network loss without increasing transformer crowding, the harmonic rejection inductor may be removed from the center of the transformer and an existing secondary coil of the transformer may be reused. The secondary coil may be reused as the harmonic rejection inductor by connecting or coupling the harmonic rejection capacitor directly in between two windings of the secondary coil, which may enable a tapped segment or portion of the secondary winding (e.g., disposed between the harmonic rejection capacitor tap point and ground) to function as a harmonic rejection inductor.

Reusing the secondary coil of the transformer as the harmonic rejection inductor may not only result in reduced area consumption, but improved overall performance of the transmitter. The performance improvement may result from the improved Q factor of the transformer, which may reduce loss in the matching network, increase the transmitter output power, reduce the transmitter current consumption, as the power amplifier of the transmitter may operate on lower power settings more frequently, and increase flexibility in the placement of a harmonic rejection cap, as tapping the secondary coil may be done from any side of the secondary coil, as long as it meets desired radio frequency performance.

It should be noted that the matching network may, in some embodiments, be disposed in series with a low-noise amplifier (LNA) of a receiver. Accordingly, the solutions provided in the foregoing and the following discussion may be applied to any suitable implementation, including transmitting matching networks, receiver matching networks, and so on.

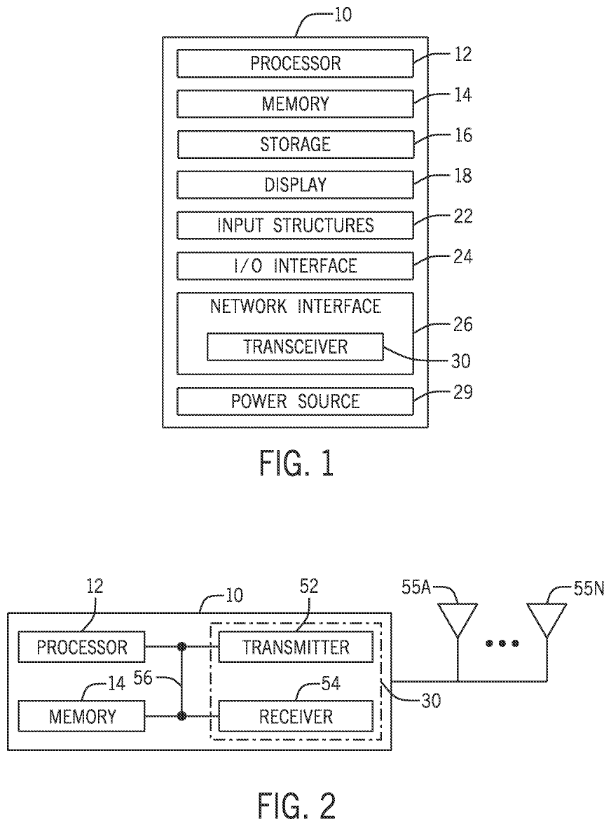

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3rd generation (3G) cellular network, universal mobile telecommunication system (UMTS), 4th generation (4G) cellular network, Long Term Evolution® (LTE) cellular network, Long Term Evolution License Assisted Access (LTE-LAA) cellular network, 5th generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have one or more antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

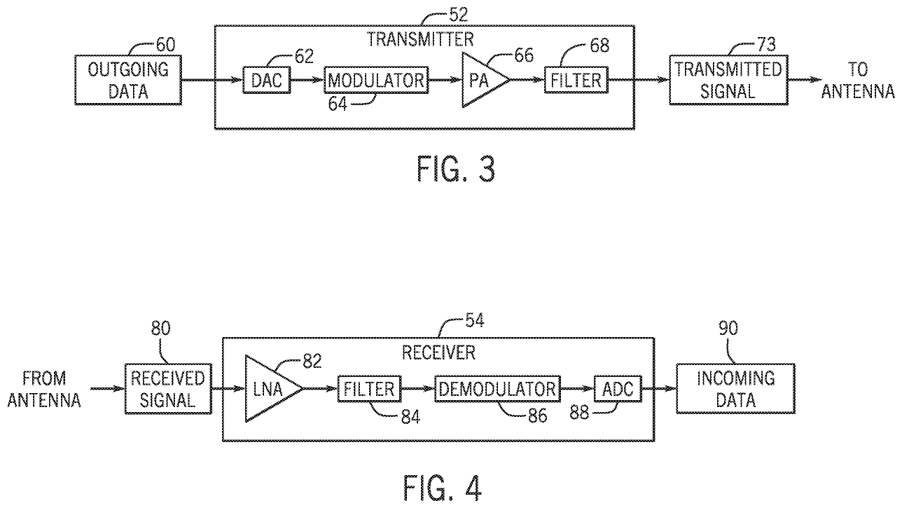

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the one or more antennas 55. A digital-to-analog converter (DAC) 62 of the transmitter 52 may convert the digital signal to an analog signal, and a modulator 64 may combine the converted analog signal with a carrier signal to generate a radio wave. A power amplifier (PA) 66 receives the modulated signal from the modulator 64. The power amplifier 66 may amplify the modulated signal to a suitable level to drive transmission of the signal via the one or more antennas 55. A filter 68 (e.g., filter circuitry and/or software) of the transmitter 52 may then remove undesirable noise from the amplified signal to generate transmitted signal 70 to be transmitted via the one or more antennas 55. The filter 68 may include any suitable filter or filters to remove the undesirable noise from the amplified signal, such as a bandpass filter, a bandstop filter, a low pass filter, a high pass filter, and/or a decimation filter.

The power amplifier 66 and/or the filter 68 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 60 via the one or more antennas 55. For example, the transmitter 52 may include a mixer and/or a digital up converter. As another example, the transmitter 52 may not include the filter 68 if the power amplifier 66 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the one or more antennas 55 in the form of an analog signal. A low noise amplifier (LNA) 82 may amplify the received analog signal to a suitable level for the receiver 54 to process. A filter 84 (e.g., filter circuitry and/or software) may remove undesired noise from the received signal, such as cross-channel interference. The filter 84 may also remove additional signals received by the one or more antennas 55 that are at frequencies other than the desired signal. The filter 84 may include any suitable filter or filters to remove the undesired noise or signals from the received signal, such as a bandpass filter, a bandstop filter, a low pass filter, a high pass filter, and/or a decimation filter. The low noise amplifier 82 and/or the filter 84 may be referred to as part of the RFFE, and more specifically, a receiver front end (RXFE) of the electronic device 10.

A demodulator 86 may remove a radio frequency carrier signal and/or extract a demodulated signal (e.g., an envelope signal) from the filtered signal for processing. An analog-to-digital converter (ADC) 88 may receive the demodulated analog signal and convert the signal to a digital signal of incoming data 90 to be further processed by the electronic device 10. Additionally, the receiver 54 may include any suitable additional components not shown, or may not include certain of the illustrated components, such that the receiver 54 may receive the received signal 80 via the one or more antennas 55. For example, the receiver 54 may include a mixer and/or a digital down converter.

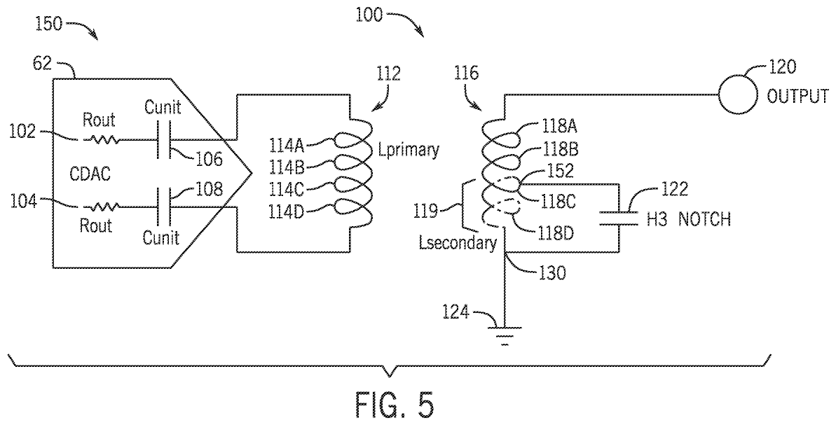

FIG. 5 is a schematic diagram of a matching network 150 wherein a harmonic rejection inductor 119 is integrated into a secondary inductor 116 of a transformer 110, according to embodiments of the present disclosure. The matching network 150 includes the DAC 62. The DAC 62 may include a capacitor DAC (CDAC) and may include resistive elements 102 and 104 (e.g., resistors) and capacitive elements 106 and 108 (e.g., capacitors). The DAC 62 is coupled to a transformer 110. The transformer 110 includes a primary inductor 112 having windings 114A. 114B, 114C, and 114D (the windings 114). The primary inductor 112 may inductively couple to a secondary inductor 116 having windings 118A, 118B, 118C, and 118D (the windings 118). The secondary inductor 116 may be coupled (e.g., via a first winding 118A) to an output port 120 of the matching network 150, and the secondary inductor 116 may be coupled (e.g., via the bottom winding 118D) to ground 124. The secondary inductor 116 may be physically, electrically, and/or operatively coupled to the output port 120 and ground 124. The output port 120 may be physically, electrically, and/or operatively coupled to the power amplifier 66.

It should be noted that, while four windings each are illustrated for the primary inductor 112 and the secondary inductor 116, each inductor may have any appropriate number n of windings. For example, the primary inductor 112 and the secondary inductor 116 may include 3 or more windings, 5 or more windings, 10 or more windings, 20 or more windings, and so on. Additionally, the number of windings on the primary inductor 112 may be unequal to the number of windings 118 on the secondary inductor 116. A harmonic rejection capacitor 122 may be coupled to any one of the windings 118 or between any two of the windings 118 at one terminal and may be coupled to ground at a second node (or terminal) 130. That is, the primary inductor 112 may have more or fewer windings than the secondary inductor 116. As will be discussed in greater detail below, the harmonic rejection inductor 119 may be integrated into the secondary inductor 116 such that the harmonic rejection inductor 119 includes a portion of the secondary inductor 116, reducing area consumption in the matching network 150 and improving overall performance of the transmitter 52.

In some scenarios, a conventional matching network may include a non-integrated harmonic rejection inductor. That is, the conventional matching network may include a stand-alone harmonic rejection inductor 119 separate from any inductors or windings of the transformer 110 of the matching network 150. In the conventional matching network, the harmonic rejection inductor 119 may be disposed at the center of the transformer 110 and inductively couple to the secondary inductor 116 and electrically coupled to an output port 120 of the matching network 100. In the conventional matching network, a harmonic rejection inductor may be disposed at the center of the transformer to reduce crowding in a matching network of the transmitter 52 or receiver 54. However, with the harmonic rejection inductor 119 disposed in the center of the transformer, drawbacks such as a reduced Q factor of both the transformer 110 and the harmonic rejection inductor 119 due to the current crowding effect (e.g., a magnetic field compression and electric field loading between neighbor metals of the harmonic rejection coil and surrounding transformer metallization) may occur. Other drawbacks may include imposing a lower limit on the diameter of the innermost winding of the primary inductor 112 or the secondary inductor 116 of the transformer 110 to fit the transformer 110 and the harmonic rejection capacitor 122, which may result in a disadvantageous increase of area consumption. Additionally, a parasitic capacitance may result, further limiting the performance of the matching network.

Reusing the secondary inductor 116 of the transformer as the harmonic rejection inductor 119, as shown in the matching network 150 of FIG. 5, may not only result in reduced area consumption in the matching network 100, but improved overall performance of the transmitter 52. The performance improvement may result from the improved Q factor of the transformer 110, which may result in less loss in the matching network 100, increase in the transmitter output power, a reduction in the transmitter current consumption, as the power amplifier 66 of the transmitter 52 may operate on lower power settings more frequently. Reusing windings of the secondary inductor 116 may also enable increased flexibility in the placement of a harmonic rejection capacitor 122, as tapping the secondary inductor 116 may be accomplished from any side of the secondary coil, as long as it meets desired radio frequency performance. Additionally, it should be noted that, while the harmonic rejection capacitor 122 is shown as coupled to the winding 118C, in some embodiments the harmonic rejection capacitor 122 may be coupled to or between any of the windings 118A, 118B, or 118D. Moreover, as was previously stated, the secondary inductor 116 may have any number n of windings, and the harmonic rejection capacitor 122 may be coupled to a winding m, a subsequent winding m+1, another subsequent winding m+2, and so on. For example, the mth winding may be the first winding of the secondary inductor 116, the second winding of the secondary inductor 116, or any other winding at the middle of the secondary inductor 116. The harmonic rejection capacitor 122 may, in some embodiments, be coupled to the last winding n, the second to last winding n−1, the third to last winding n−2, and so on. The harmonic rejection capacitor 122 may, in some embodiments, be coupled between any of the windings mentioned above or any other appropriate or available windings of the secondary inductor 116.

To achieve reduced loss in the matching network 100 without increasing transformer 110 crowding, the harmonic rejection inductor 119 may be removed from the center of the transformer 110 and the existing secondary inductor 116 of the transformer 110 may be reused. The secondary inductor 116 may be reused as the harmonic rejection inductor by coupling the harmonic rejection capacitor 122 directly to windings 118 of the secondary inductor 116, as illustrated in the matching network 150, which may enable a portion of the secondary inductor 116 between the harmonic rejection capacitor 122 tap point 152 and ground 124 (e.g., a tapped segment) to function as the harmonic rejection inductor 119.

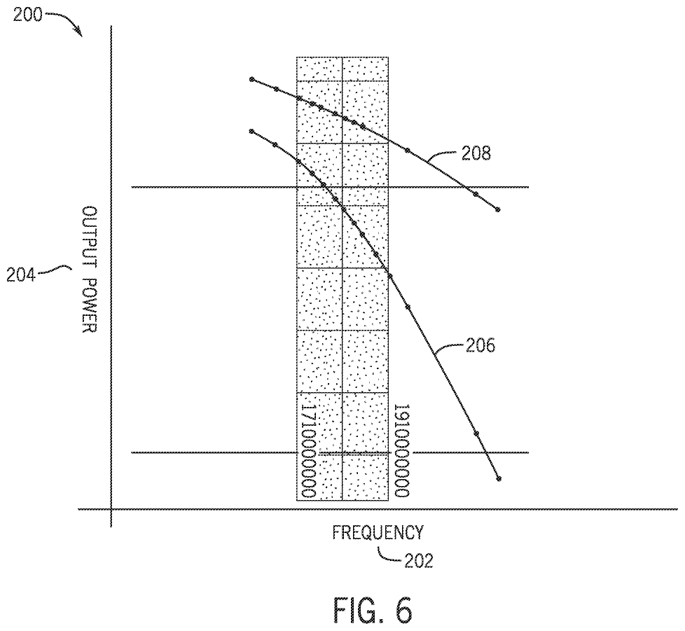

FIG. 6 is a plot 200 illustrating output power of the transmitter 52 when the transmitter 52 is coupled to the matching network 150 and when the transmitter is coupled to a matching network wherein the harmonic rejection inductor 119 is not integrated into the secondary coil of the transformer, according to embodiments of the present disclosure. The plot 200 includes a horizontal or x-axis 202 representing frequencies that the transmitter 52 may transmit a signal and a vertical or y-axis 204 representing the output power that the transmitter 52 may use to transmit the signal. The curve 206 represents the output power achievable as a function of frequency via the matching network having a non-integrated harmonic rejection inductor 119 and the curve 208 represents the output power achievable as a function of frequency via the matching network 150. As may be observed, the curve 208 exhibits a substantially greater transmitter output power than the curve 206. Accordingly, it may be appreciated that integrating the harmonic rejection inductor 119 into the secondary inductor 116 may increase transmitter output power and thus enhance performance of the transmitter 52.

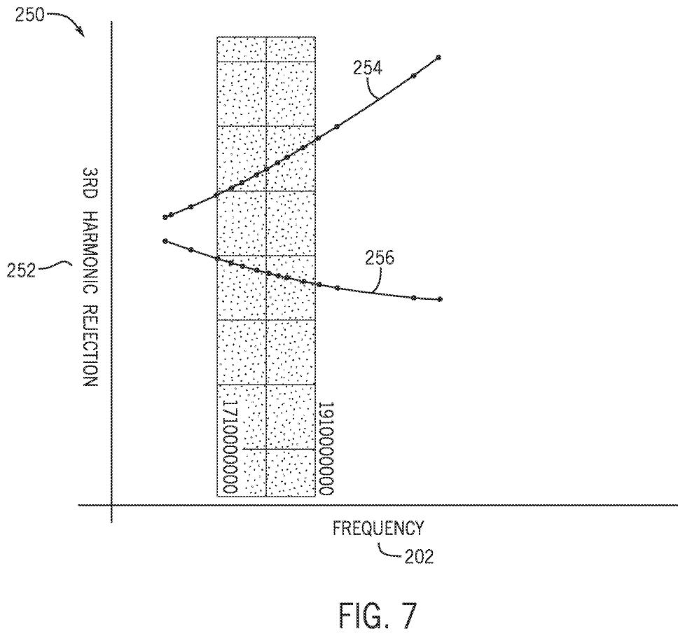

FIG. 7 is a plot 250 illustrating harmonic rejection of the 3rd harmonic in the transmitter 52 when the transmitter 52 is coupled to the matching network 150 and when the transmitter 52 is coupled to a matching network wherein the harmonic rejection inductor 119 is not integrated into the secondary coil of the transformer 110, according to embodiments of the present disclosure. The plot 250 includes the x-axis 202 representing frequency and a vertical or y-axis 252 representing harmonic rejection of an input signal to the transmitter 52 and/or an input signal of the transformer 110 in decibels (dB) of the 3^{rd} harmonic. The curve 254 represents harmonic rejection when the transmitter 52 is coupled to the matching network having a non-integrated harmonic rejection inductor 119 and the curve 256 represents harmonic rejection when the transmitter 52 is coupled to the matching network 150. As may be observed, the curve 254 exhibits less harmonic rejection of the input signal to the transmitter 52 and/or an input signal to the transformer 110 than the curve 256. Accordingly, it may be appreciated that integrating the harmonic rejection inductor 119 into the secondary inductor 116 may enhance harmonic rejection of the 3rd harmonic and thus enhance performance of the transmitter 52.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. A transmitter, comprising:
a digital-to-analog converter (DAC);
a first inductor coupled to the DAC;
a second inductor inductively coupled to the first inductor, the second inductor comprising one or more windings; and
a capacitor coupled at a first terminal of the capacitor to the one or more windings and at a second terminal of the capacitor to ground.

2. The transmitter of claim 1, wherein the one or more windings comprise a first winding, a second winding, a third winding, and a fourth winding.

3. The transmitter of claim 2, wherein the second inductor is coupled to an output port at the first winding.

4. The transmitter of claim 2, wherein the second inductor is coupled to ground at the fourth winding.

5. The transmitter of claim 2, wherein the second winding is coupled between the first winding and the third winding.

6. The transmitter of claim 2, wherein the third winding is coupled between the second winding and the fourth winding.

7. The transmitter of claim 2, wherein the capacitor is coupled at the first terminal to the third winding of the one or more windings.

8. The transmitter of claim 1, wherein the capacitor comprises a harmonic rejection capacitor that is configured to perform harmonic rejection for a second harmonic of an input signal to the transmitter.

9. The transmitter of claim 1, wherein the capacitor comprises a harmonic rejection capacitor that is configured to perform harmonic rejection for a third harmonic of an input signal to the transmitter.

10. The transmitter of claim 1, wherein the capacitor comprises a harmonic rejection capacitor that is configured to perform harmonic rejection for a second harmonic and a third harmonic of an input signal to the transmitter.

11. A transformer, comprising:
a first inductor; and
a second inductor configured to inductively couple to the first inductor and coupled to a capacitor, the capacitor coupled between windings of the second inductor and configured to perform harmonic rejection of an input signal to the transformer.

12. The transformer of claim 11, wherein the second inductor comprises n windings, and the capacitor is coupled between an nth winding and an n−1 winding of the second inductor at a first terminal of the capacitor and is coupled to ground at a second terminal of the capacitor.

13. The transformer of claim 11, wherein the second inductor comprises n windings, and the capacitor is coupled between an n−1 winding and an n−2 winding of the second inductor at a first terminal of the capacitor and is coupled to ground at a second terminal of the capacitor.

14. The transformer of claim 11, wherein the second inductor comprises n windings starting at an mth winding, and the capacitor is coupled between the mth winding and an m+1 winding of the second inductor at a first terminal of the capacitor and is coupled to ground at a second terminal of the capacitor.

15. A system, comprising:
a digital-to-analog converter (DAC);
a transformer coupled to an output of the DAC, the transformer comprising
a first inductor comprising a first plurality of windings; and
a second inductor comprising a second plurality of windings, the second inductor configured to inductively couple to the first inductor,
a capacitor coupled at a tap point of the second plurality of windings; and
an amplifier coupled to an output of the second inductor.

16. The system of claim 15, wherein the capacitor is coupled at a first terminal of the capacitor to a winding at the tap point and coupled at a second terminal of the capacitor to ground.

17. The system of claim 16, wherein the second plurality of windings comprises n number of windings in between the tap point and the ground, wherein the n number of windings and the capacitor are configured to perform harmonic rejection.

18. The system of claim 17, wherein the n number of windings and the capacitor are configured to perform harmonic rejection for a second harmonic, a third harmonic, or both, of an input signal of the transformer.

19. The system of claim 15, wherein the first plurality of windings comprises fewer windings than the second plurality of windings.

20. The system of claim 15, wherein the first plurality of windings comprises more windings than the second plurality of windings.
